(19) United States
(12) Patent Application Publication
(10) Pub. No.: US 2020/0067026 A1
(43) Pub. Date: Feb. 27, 2020

(54) DISPLAY PANEL, METHOD FOR MANUFACTURING THE SAME AND DISPLAY DEVICE

(71) Applicants: Ordos Yuansheng Optoelectronics Co., Ltd., Ordos (CN); BOE TECHNOLOGY GROUP CO., LTD., Beijing (CN)

(72) Inventor: Zihua LI, Beijing (CN)

(21) Appl. No.: 16/407,581

(22) Filed: May 9, 2019

(30) Foreign Application Priority Data
Aug. 27, 2018 (CN) 201810981506.3

(51) Int. Cl. H01L 51/56; H01L 51/52; H01L 51/00; H05K 3/32; H05K 1/18

(52) U.S. Cl. CPC H01L 51/56; H01L 51/5237; H01L 2251/53; H05K 3/323; H05K 1/189; H01L 51/0011

(57) ABSTRACT

The present disclosure provides a display panel, a method for manufacturing the same, and a display device. The display panel includes a binding region which includes a PAD region. The PAD region includes a connect layer which is composed of patterns of multiple sharp protrusions.

### CROSS REFERENCE TO RELATED APPLICATION

This application is based upon, claims the benefit of, and priority to Chinese Patent Application No. 201810981506.3, filed on Aug. 27, 2018, the entire contents thereof are incorporated herein by reference.

### TECHNICAL FIELD

The present disclosure relates to the technical field of display, and particularly to a display panel, a method for manufacturing the same and a display device.

### BACKGROUND

During a manufacturing process of a display device in the related art, an integrated circuit (IC) is bound to a binding region of the display panel, and then a flexible printed circuit (FPC) is attached.

### SUMMARY

According to a first aspect of the present disclosure, embodiments of the present disclosure provide a display panel, including: a binding region which includes a PAD region, wherein the PAD region includes a connect layer which is composed of patterns of multiple sharp protrusions.

According to an embodiment of the present disclosure, a width of each of the sharp protrusions is no larger than one-half of a diameter of an anisotropic conductive film particle.

According to an embodiment of the present disclosure, the width of each of the sharp protrusions is no less than one third of the diameter of the anisotropic conductive film particle.

According to an embodiment of the present disclosure, the PAD region further includes: a base substrate, a buffer layer, and a source/drain metal layer, which are stacked from bottom to top, wherein the connect layer is provided between the buffer layer and the source/drain metal layer.

According to an embodiment of the present disclosure, a height of each of the sharp protrusions is at least twice a thickness of source/drain metal in the source/drain metal layer.

According to an embodiment of the present disclosure, a distance between any two adjacent sharp protrusions is no larger than one-half the diameter of the anisotropic conductive film particle.

According to an embodiment of the present disclosure, the multiple sharp protrusions are uniformly distributed on the buffer layer in an array.

According to an embodiment of the present disclosure, the sharp protrusions are provided with a shape of a sharp convex.

According to an embodiment of the present disclosure, the display panel is an organic light-emitting diode display panel.

According to a second aspect of the present disclosure, the embodiments of the present disclosure further provide a display device, including the display panel as described above.

Further, the display device further includes a flexible printed circuit, wherein the flexible printed circuit is bound to the display panel in the PAD region by anisotropic conductive film particles.

According to a third aspect of the present disclosure, the embodiments of the present disclosure further provide a method for manufacturing the display panel, including:

forming a buffer layer on a base substrate;

forming a connect layer composed of patterns of multiple sharp protrusions on the buffer layer; and

forming a source/drain metal layer on the connect layer.

According to an embodiment of the present disclosure, forming a connect layer composed of patterns of multiple sharp protrusions on the buffer layer, comprises:

depositing a connect material on the buffer layer; and

patterning the connect material by photolithography process with a prefabricated mask to obtain the connect layer composed of the patterns of the multiple sharp protrusions.

According to an embodiment of the present disclosure, the connect material is silicon nitride or silicon oxide.

### BRIEF DESCRIPTION OF THE DRAWINGS

By reading the detailed descriptions of non-restrictive embodiments with reference to the following drawings, other features, objects, and advantages of the present application will become more apparent.

FIG. 1 is a schematic diagram of a binding region of a display panel in the related art;

FIG. 2 is a schematic structural diagram of a PAD region in the related art;

FIG. 3 is a schematic cross-sectional structural diagram of the PAD region in a display panel provided by the embodiments of the present disclosure;

FIG. 4 is a schematic plane structural diagram of a CNT layer provided by the embodiments of the present disclosure;

FIG. 5 is a schematic structural diagram of a display panel provided by the embodiments of the present disclosure;

FIG. 6 to FIG. 9 are schematic flow charts of manufacturing the display panel provided by the embodiments of the present disclosure.

### DETAILED DESCRIPTION

The present application will be further described in detail in conjunction with the drawings and the embodiments. It is understood that specific embodiments described herein are merely illustrative of the relevant disclosure. It should also be noted that, for the convenience of description, only parts related to the present disclosure are shown in the drawings.

It should be noted that the embodiments of the present disclosure and the features in the embodiments may be combined with each other without conflict. The present application will be described in detail below with reference to the accompanying drawings.

Thicknesses of various components and sizes, shapes of regions in the accompanying drawings do not reflect the true proportions of the various components, and are merely intended to illustrate contents of the present application.

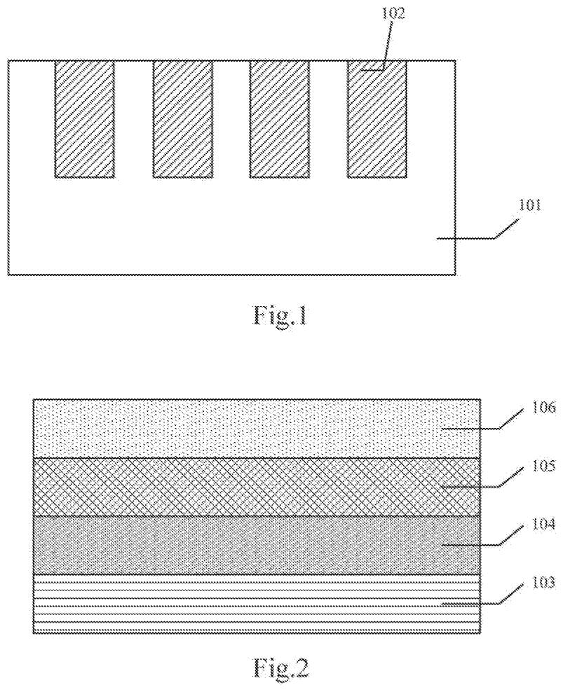

First, as shown in FIG. 1, a schematic diagram of a binding region of the display panel of the prior art is shown. A region for binding an IC in the display panel is referred to as a binding region 101. Also, a region in the binding region 101 in where the IC is connected to lines of the display panel is referred to as a PAD region 102. A PAD region 102 included in a binding region 101 of the display panel in the FIG. 1 is enlarged to obtain a schematic structural diagram of the PAD region 102 as shown in FIG. 2. The PAD region 102 includes a base substrate 103, a buffer layer 104, a CNT (connect) layer 105, and source/drain (SD) metal layer 106 which are provided and stacked from bottom to top. Viewed from top to bottom, the SD metal layer 106 is found to be a flat layer without any other design pattern. Terms, such as “upper” and “lower” in the present disclosure, merely mean relative positional relationship of the above respective layers. Referring to FIG. 2, “upper” in the present disclosure may be understood to mean that the buffer layer 104 is located above the base substrate 103, the CNT layer is located above the buffer layer 104 and, of course, the buffer layer 104 is located below the CNT layer 105.

The following problem exists in the prior art: the display panel is bound to the FPC by anisotropic conductive film (ACF) particles in its PAD region 102. Under normal circumstances, an insulating film of the ACF particles is broken under the effect of binding pressure and temperature to turn on the display panel and the FPC. However, during the binding process, there is always a problem that the insulating film of the ACF particles is not broken due to insufficient binding pressure or insufficient temperature, thereby causing abnormal binding and poor contact of the display panel. In response to this problem in the prior art, the embodiments of the present disclosure improve the PAD region 102 in the display panel by patterning the CNT layer in the PAD region 102. The patterned CNT layer is composed of patterns of multiple sharp protrusions. Compared with the prior art, the sharp protrusions can increase the binding pressure between the display panel and a FPC, so that the insulating film of the ACF particles is more easily broken, thereby improving yield of the display panel.

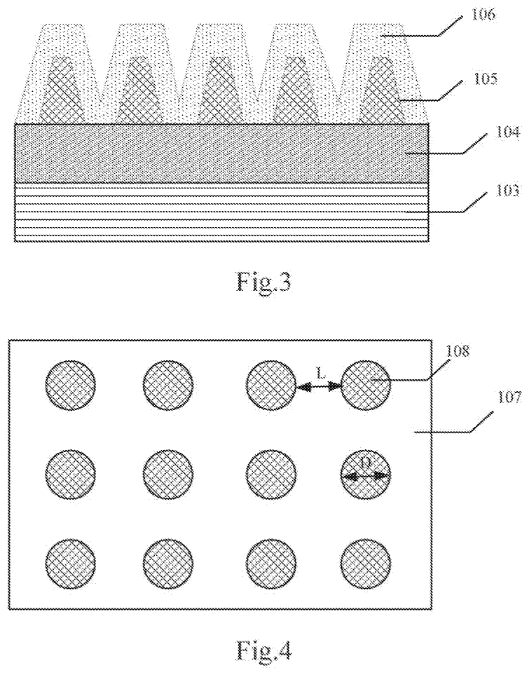

As shown in FIG. 3, it is a schematic cross-sectional structural diagram of the PAD region in a display panel provided by the embodiments of the present disclosure.

Referring to FIG. 1 and FIG. 3, the display panel includes the binding region 101, the PAD region 102 is included in the binding region 101. The PAD region 102 includes the base substrate 103, the buffer layer 104, the CNT layer 105, and the SD metal layer 106, which are provided and stacked from bottom to top.

In the embodiment, the CNT layer 105 is composed of the patterns of the multiple sharp protrusions.

Further, the base substrate 103 may adopt a rigid substrate such as a glass substrate or a substrate with a good flexibility, or may adopt a flexible substrate such as a plastic substrate.

In order to make the insulating film of the ACF particles more easily to be broken, as shown in FIG. 4, a schematic plane structural diagram of the CNT layer is shown. An unreserved region 107 in the CNT layer and a reserved region 108 in the CNT layer are included in FIG. 4, and the reserved region 108 in the CNT layer is composed of the patterns of the multiple sharp protrusions.

In an embodiment, a width D of each of the sharp protrusions may be no larger than one-half of diameter of the ACF particles, so that the insulating film of the ACF particles can be more easily broken.

Further, the width D of each of the sharp protrusions may further be no less than one third of the diameter of the ACF particles. If, the width D of the sharp protrusions is too small, the density of the sharp protrusions is too large, which makes a cracking effect of the insulating film of the ACF particles which are deteriorated.

Presently, a diameter range of the ACF particles is usually between 3 um and 10 um. Taking that the diameter of the ACF particles is 3 um as an example, a range of maximum width D of each of the sharp protrusions may be between 1 um to 1.5 um.

In an embodiment, a height H of each of the sharp protrusions may be at least twice a thickness of source/drain metal in the source/drain metal layer, which may further make the insulating film of the ACF particles to be more easily broken.

In an embodiment, a distance L between any two adjacent sharp protrusions may be no larger than one-half the diameter of the ACF particles. If the distance L between any two adjacent sharp protrusions is too large, the density of the sharp protrusions is too small, and it is difficult to pierce the insulating film of the ACF particles.

Where the diameter of the ACF particles is 3 um, as an example, the distance L between any two adjacent sharp protrusions may be less than or equal to 1.5 um.

In an embodiment, the patterns of multiple sharp protrusions may be uniformly distributed on the buffer layer 104 in an array.

In an embodiment, the sharp protrusions may be provided with a shape of a sharp convex.

In the embodiments of the present disclosure, the display panel may be an organic light emitting diode (OLED) display panel.

The display panel provided by the embodiments of the present disclosure may be applied to display devices such as televisions, digital cameras, mobile phones, tablet computers, notebook computers, watches, navigators, etc.

The display panel provided by the embodiments of the present disclosure includes the PAD region in the binding region of the display panel. The PAD region includes the CNT layer which is composed of the patterns of the multiple sharp protrusions. Compared with the related art, the sharp protrusions in the CNT layer can increase the binding pressure between the display panel and a FPC, so that the insulating film of the ACF particles is more easily broken, thereby avoiding the problem of the poor contact of the display panel due to the insulating film of ACF particles not being broken, and improving the yield of the display panel.

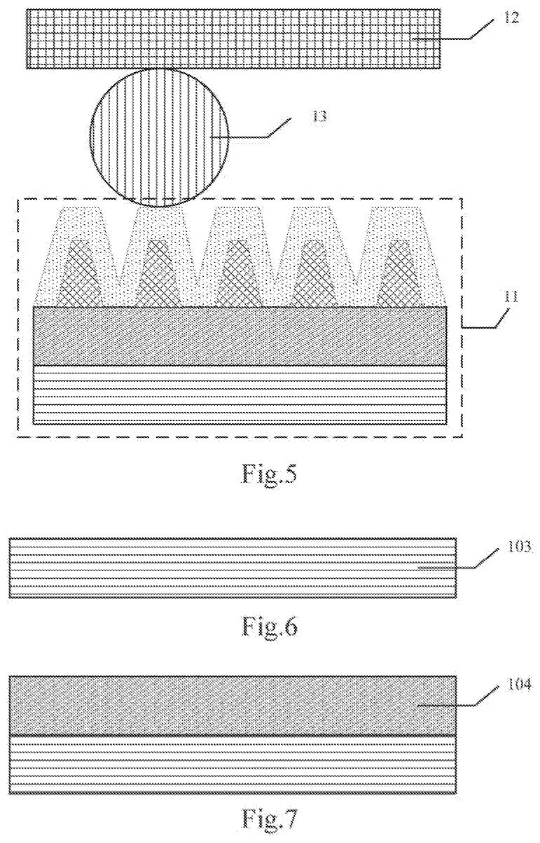

Based on the above display panel, the embodiments of the present disclosure further provide a display device, as shown in FIG. 5 which is the schematic structural diagram of the display panel. The display device includes the display panel 11 as described above, and specific structures of the display panel 11 will not be described herein.

Further, the display device may include a FPC 12, where, in the embodiment, the FPC 12 is bound to the display panel 11 in the PAD region by the ACF particles 13.

When the FPC 12 is bound to the display panel 11, the FPC 12 and the display panel 11 need to be pressed together forcibly. During this process, the ACF particles 13 located between the FPC 12 and the display panel 11 are stressed. Since the CNT layer 105 is composed of the patterns of the multiple sharp protrusions, the binding pressure between the FPC 12 and the display panel 11 is increased, and the insulating layer of the ACF particles 13 is more easily to be broken, so that the FPC 12 and the display panel 11 are turned on.

The display device in the embodiments of the present disclosure may be any product or component with a display function, such as a mobile phone, a tablet computer, a display, a notebook computer, a digital photo frame, a navigator, etc.

It should be noted that other essential components of the display device are understood by those of ordinary skill in the art, and are not described herein.

Based on the same disclosed concept, the embodiments of the present disclosure further provide a method for manufacturing the display panel as described above. As shown in FIG. 6 to FIG. 9, an exemplary process is described below in conjunction with the accompanying drawings as follows.

As shown in FIG. 6, a base substrate 103 is provided, which is, for example, a glass substrate, a plastic substrate, etc.

As shown in FIG. 7, a buffer layer 104 is formed on the base substrate 103.

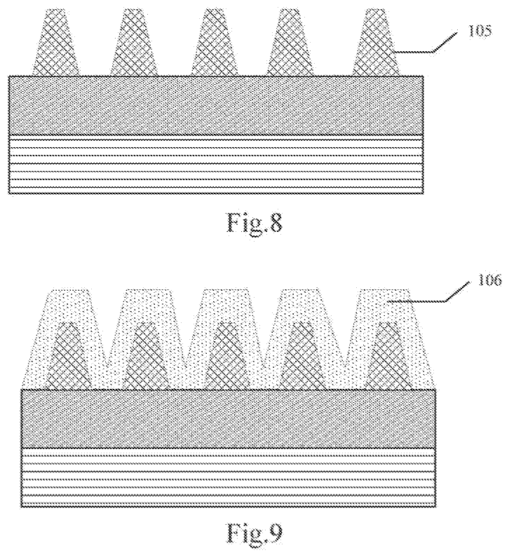

As shown in FIG. 8, a CNT layer 105 composed of patterns of the multiple sharp protrusions is formed on the buffer layer 104.

Specifically, the method may include the following steps.

CNT material is deposited on the buffer layer 104. The CNT material may be, but is not limited to, silicon nitride or silicon oxide.

The CNT material is patterned by photolithography process with a prefabricated mask to obtain the CNT layer composed of the patterns of the multiple sharp protrusions.

As shown in FIG. 9, a SD metal layer 106 is formed on the CNT layer 105.

A method for manufacturing the display panel provided by the embodiments of the present disclosure, the buffer layer is formed on the base substrate, and a CNT layer composed of the patterns of the multiple sharp protrusions is formed on the buffer layer, and the SD metal layer is formed on the CNT layer. Compared with the related art, the sharp protrusions in the CNT layer can increase the binding pressure between the display panel and the FPC, so that the insulating film of the ACF particles is more easily broken, thereby avoiding the problem of the poor contact of the display panel due to that the insulating film of ACF particles is not broken, and improving yield of the display panel.

The above description is merely preferred embodiments of the present application and a description of principles of the applied technology. It should be understood by those skilled in the art that the scope of the disclosure covered in the present application is not limited to a specific combination of the above technical features. It should further cover other technical solutions formed by any combination of the above technical features or equivalent features thereof without departing from the disclosed concept. For example, the above features and the technical features disclosed in the present application (but not limited to) with similar functions are replaced by each other to form a technical scheme.

1. A display panel, comprising:
a binding region comprising a PAD region, the PAD region comprising a connect layer which is composed of patterns of multiple sharp protrusions.

2. The display panel according to claim 1, wherein a width of each of the sharp protrusions is no larger than one-half of a diameter of an anisotropic conductive film particle.

3. The display panel according to claim 2, wherein the width of each of the sharp protrusions is no less than one third of the diameter of the anisotropic conductive film particle.

4. The display panel according to claim 1, wherein a distance between any two adjacent sharp protrusions is no larger than one-half the diameter of the anisotropic conductive film particle.

5. The display panel according to claim 1, wherein the sharp protrusions are provided with a shape of a sharp convex.

6. The display panel according to claim 1, wherein the PAD region further comprises: a base substrate, a buffer layer, and a source/drain metal layer that are stacked from bottom to top, wherein the connect layer is provided between the buffer layer and the source/drain metal layer.

7. The display panel according to claim 6, wherein the width of each of the sharp protrusions is no larger than one-half of the diameter of the anisotropic conductive film particle.

8. The display panel according to claim 7, wherein the width of each of the sharp protrusions is no less than one third of the diameter of the anisotropic conductive film particles.

9. The display panel according to claim 6, wherein a height of each of the sharp protrusions is at least twice a thickness of source/drain metal in the source/drain metal layer.

10. The display panel according to claim 6, wherein the distance between any two adjacent sharp protrusions is no larger than one-half the diameter of the anisotropic conductive film particle.

11. The display panel according to claim 6, wherein the multiple sharp protrusions are uniformly distributed on the buffer layer in an array.

12. The display panel according to claim 6, wherein the sharp protrusions are provided with the shape of the sharp convex.

13. The display panel according to claim 6, wherein the display panel is an organic light-emitting diode display panel.

14. A display device, comprising:
a display panel comprising a binding region which comprises a PAD region, wherein the PAD region comprises a connect layer which is composed of patterns of multiple sharp protrusions.

15. The display device according to claim 14, wherein the PAD region further comprises: a base substrate, a buffer layer, and a source/drain metal layer that are stacked from bottom to top, wherein the connect layer is provided between the buffer layer and the source/drain metal layer.

16. The display device according to claim 15, wherein the display device further comprises a flexible printed circuit, wherein the flexible printed circuit is bound to the display panel in the PAD region by anisotropic conductive film particles.

17. The display device according to claim 16, wherein a width of each of the sharp protrusions is no larger than one-half of a diameter of the anisotropic conductive film particle.

18. A method for manufacturing the display panel, comprising:
forming a buffer layer on a base substrate;
forming a connect layer composed of patterns of multiple sharp protrusions on the buffer layer; and
forming a source/drain metal layer on the connect layer.

19. The method according to claim 18, wherein forming a connect layer composed of patterns of the multiple sharp protrusions on the buffer layer, comprises:
depositing connect material on the buffer layer; and
patterning the connect material by photolithography process with a prefabricated mask to obtain the connect layer composed of the patterns of the multiple sharp protrusions.

20. The method according to claim 19, wherein the connect material is silicon nitride or silicon oxide.
